(19) United States
(12) Patent Application Publication
(10) Pub. No.: US 2024/0395351 A1
(43) Pub. Date: Nov. 28, 2024

(54) SEMICONDUCTOR DEVICE AND OPERATING METHOD OF SEMICONDUCTOR DEVICE CAPABLE OF REDUCING DATA ERROR RATE

(71) Applicant: SK hynix Inc., Icheon (KR)

(72) Inventor: Kyu Sung KIM, Icheon (KR)

(21) Appl. No.: 18/462,056

(22) Filed: Sep. 6, 2023

(30) Foreign Application Priority Data
May 23, 2023 (KR) 10-2023-0066168

(51) Int. Cl. G11C 29/52; G11C 7/12; G11C 7/22

(52) U.S. Cl. CPC G11C 29/52; G11C 7/12; G11C 7/22

(57) ABSTRACT

A semiconductor device may include a control circuit generating a current direction control signal, a row address signal, and a column address signal, a current direction control circuit selectively providing first and second bias voltages to row and column voltage lines, a row decoder selecting at least one of word lines and driving the selected word line to a voltage level of the row voltage line, a column decoder selecting at least one of bit lines and driving the selected bit line to a voltage level of the column voltage line, a memory cell array including a plurality of memory cells at intersecting locations of the word lines and the bit lines, and a data output circuit detecting data stored in selected memory cells after the start of a read operation and detecting and correcting an error of the detected data.

### CROSS-REFERENCE TO RELATED APPLICATION

This application claims priority under 35 U.S.C. § 119 to Korean Patent Application No. 10-2023-0066168 filed on May 23, 2023, which is incorporated herein by reference in its entirety.

### BACKGROUND

### 1. Technical Field

Embodiments relate to an integrated circuit technology and, more particularly, to a semiconductor device and an operating method of a semiconductor device, which can reduce a data error rate.

### 2. Related Art

Recently, as an electronic device is reduced in size, has low power consumption and high performance, and is diversified, a semiconductor device capable of storing information is desirable for various electronic devices, such as computers and portable communication devices. The semiconductor device may be basically divided into a volatile memory device and a nonvolatile memory device. The volatile memory device can retain data only in the state in which power is supplied to the volatile memory device. The nonvolatile memory device can retain data although power is not supplied to the nonvolatile memory device.

The nonvolatile memory device representatively includes NAND type memory. Next-generation memory that is now being developed includes ferroelectric RAM (FRAM), magnetic RAM (MRAM), phase-change RAM (PRAM), polymer RAM (PoRAM), and resistance RAM (ReRAM).

### SUMMARY

In an embodiment, a semiconductor device may include a control circuit configured to generate a current direction control signal, a row address signal, and a column address signal, based on a command signal, an address signal, a data signal, and an error correction code (ECC) information signal, a current direction control circuit configured to selectively provide a first bias voltage and a second bias voltage to a row voltage line and a column voltage line, based on the current direction control signal, a row decoder configured to select at least one word line, among a plurality of word lines, based on the row address signal and configured to drive the selected word line to a voltage level of the row voltage line, a column decoder configured to select at least one bit line, among a plurality of bit lines, based on the column address signal and configured to drive the selected bit line to a voltage level of the column voltage line, a memory cell array comprising a plurality of memory cells that are disposed at intersecting locations of the plurality of word lines and the plurality of bit lines, and a data output circuit configured to detect data that has been stored in selected memory cells, among the plurality of memory cells, after a start of a read operation and configured to detect, correct, and output an error of the detected data.

In an embodiment, a semiconductor device may include a control circuit configured to generate a current direction control signal, a row address signal, and a column address signal based on an error correction code (ECC) information signal, after a start of a read operation or whenever a set time interval elapses, a current direction control circuit configured to selectively provide a first bias voltage and a second bias voltage to a row voltage line and a column voltage line, based on the current direction control signal, a row decoder configured to select at least one word line, among a plurality of word lines, based on the row address signal and configured to drive the selected word line to a voltage level of the row voltage line, a column decoder configured to select at least one bit line, among a plurality of bit lines, based on the column address signal and configured to drive the selected bit line to a voltage level of the column voltage line, and an ECC circuit configured to detect and correct an error of data that is output after the start of the read operation, and configured to generate an ECC information signal indicating a number of corrected data, locations of memory cells that have output the corrected data, and a type of error of the corrected data.

In an embodiment, an operating method of a semiconductor device may include a read operation of outputting data stored in a selected memory cell, an operation of receiving error correction code (ECC) information from an ECC circuit that detects and corrects an error of the data after a start of a read operation, an operation of determining whether a number of corrected data is greater than a set number based on the ECC information, an operation of identifying locations of memory cells that have output the corrected data and a type of error of the corrected data based on the ECC information when the number of data corrected is greater than the set number, and an operation of providing a current having a direction based on the type of error to the memory cells that have output the corrected data.

In an embodiment, an operating method of a semiconductor device may include an operation of receiving error correction code (ECC) information whenever a set time interval elapses, an operation of identifying locations of memory cells that have output corrected data and a type of error of the corrected error based on the ECC information, and an operation of providing a current having a direction based on the type of error to the memory cells that have output the corrected data.

### BRIEF DESCRIPTION OF THE DRAWINGS

FIG. 1 is a diagram illustrating a semiconductor device according to an embodiment of the present disclosure.

FIGS. 2A, 2B, and 2C are diagrams for describing a reset write operation, a set write operation, and a read operation for a memory cell that is included in a semiconductor device according to an embodiment of the present disclosure.

FIGS. 3A and 3B are diagrams for describing a drift phenomenon and re-write operation of a memory cell that is included in a semiconductor device according to an embodiment of the present disclosure.

FIG. 4 is a flowchart for describing an operating method of a semiconductor device according to an embodiment of the present disclosure.

FIG. 5 is a flowchart for describing an operating method of a semiconductor device according to another embodiment of the present disclosure.

FIG. 6 is a flowchart for describing an operating method of a semiconductor device according to still another embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device and an operating method of a semiconductor device, which can reduce a data error rate attributable to a drift phenomenon.

It is possible to improve the reliability of the semiconductor device by reducing a data error rate of the semiconductor device.

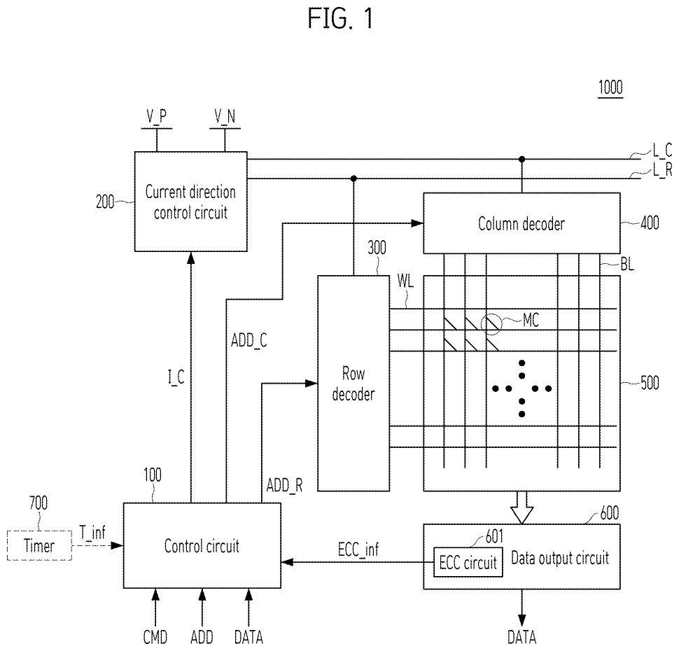

FIG. 1 is a diagram illustrating a semiconductor device according to an embodiment of the present disclosure.

Referring to FIG. 1, a semiconductor device 1000 according to an embodiment of the present disclosure may include a control circuit 100, a current direction control circuit 200, a row decoder 300, a column decoder 400, a memory cell array 500, and a data output circuit 600. Furthermore, the semiconductor device 1000 according to an embodiment of the present disclosure may further include a timer 700.

The control circuit 100 may store data in the memory cell array 500 by controlling the current direction control circuit 200, the row decoder 300, and the column decoder 400, based on a command signal CMD, an address signal ADD, and a data signal DATA, and may output, to the outside of the semiconductor device 1000, the data that has been stored in the memory cell array 500 through the data output circuit 600. In this case, an operation of storing data in the memory cell array 500 may be called a write operation. An operation of outputting, to the outside of the semiconductor device 1000, the data that has been stored in the memory cell array 500 may be called a read operation.

For example, the control circuit 100 that performs the write operation or the read operation may generate a current direction control signal I_C, a row address signal ADD_R, and a column address signal ADD_C, based on the command signal CMD, the address signal ADD, and the data signal DATA.

More specifically, for example, the control circuit 100 may generate the current direction control signal I_C, based on the command signal CMD and the data signal DATA, and may provide the current direction control signal I_C to the current direction control circuit 200.

The control circuit 100 may generate the row address signal ADD_R based on the command signal CMD and the address signal ADD, and may provide the row address signal ADD_R to the row decoder 300.

The control circuit 100 may generate the column address signal ADD_C based on the command signal CMD and the address signal ADD, and may provide the column address signal ADD_C to the column decoder 400.

Furthermore, the control circuit 100 according to an embodiment of the present disclosure may generate the current direction control signal I_C, the row address signal ADD_R, and the column address signal ADD_C, based on an error correction code (ECC) information signal ECC_inf and an interval information signal T_inf. In an embodiment, the ECC information signal ECC_inf may include information with regard to the number of data having an error corrected after the start of a read operation and locations of memory cells that have output the corrected data and the type of error. For example, the ECC information signal ECC_inf may indicate the number of corrected data after the start of a read operation, locations of memory cells that have output the corrected data, and a type of error of the corrected data. Furthermore, the interval information signal T_inf may be a signal that is generated whenever a set time elapses.

For example, the control circuit 100 may generate the row address signal ADD_R and the column address signal ADD_C based on one or both of the ECC information signal ECC_inf and the interval information signal T_inf, and may provide the generated row address and column address signals ADD_R and ADD_C to the row decoder 300 and the column decoder 400, respectively. In this case, when it is determined that the number of data having an error corrected by the ECC circuit 601 based on the ECC information signal ECC_inf is greater than a set number, the control circuit 100 may generate the row address signal ADD_R and the column address signal ADD_C corresponding to the locations of memory cells that have output the corrected data. Furthermore, when it is determined that a set time has elapsed based on the interval information signal T_inf, the control circuit 100 may generate the row address signal ADD_R and the column address signal ADD_C corresponding to the locations of memory cells that have output the corrected data based on the ECC information signal ECC_inf.

Thereafter, the control circuit 100 may identify the type of error of the data corrected based on the ECC information ECC_inf, and may generate the current direction control signal I_C based on the identified type of error.

The current direction control circuit 200 may selectively provide a first bias voltage (e.g., a positive bias voltage) V_P and a second bias voltage (e.g., a negative bias voltage) V_N to a first voltage line (e.g., a row voltage line) L_R and a second voltage line (e.g., a column voltage line) L_C, based on the current direction control signal I_C.

For example, when providing the positive bias voltage V_P to the row voltage line L_R based on the current direction control signal I_C, the current direction control circuit 200 may provide the negative bias voltage V_N to the column voltage line L_C. Furthermore, when providing the positive bias voltage V_P to the column voltage line L_C based on the current direction control signal I_C, the current direction control circuit 200 may provide the negative bias voltage V_N to the row voltage line L_R. Specifically, when the current direction control signal I_C has a first value indicating a first type of error (e.g., a reset error), the current direction control circuit 200 may provide the positive bias voltage V_P to the row voltage line L_R and the negative bias voltage V_N to the column voltage line L_C. When the current direction control signal I_C has a second value indicating a second type of error (e.g., a set error), the current direction control circuit 200 may provide the positive bias voltage V_P to the column voltage line L_C and the negative bias voltage V_N to the row voltage line L_R.

The row decoder 300 may select at least one of a plurality of word lines WL based on the row address signal ADD_R, and may drive the selected word line WL to the voltage level of the row voltage line L_R.

The column decoder 400 may select at least one of a plurality of bit lines BL based on the column address signal ADD_C, and may drive the selected bit line BL to the voltage level of the column voltage line L_C.

The memory cell array 500 may include a plurality of memory cells MC, and may be an area in which the plurality of word lines WL and the plurality of bit lines BL intersect. In this case, the memory cell MC may be disposed at the location at which one word line WL and one bit line BL intersect. Each memory cell MC may be electrically connected between the word line WL and the bit line BL. Furthermore, the memory cell MC may store data in a first state (e.g., a set state) or a second state (e.g., a reset state) depending on the polarity of a voltage that is provided by each of the word line WL and the bit line BL. That is, the memory cell MC may store set data or reset data depending on the direction in which a current flows into the memory cell MC. The memory cell MC may be self-selecting memory including a chalcogenide alloy.

The data output circuit 600 may detect data that has been stored in the memory cell MC through the word line WL or the bit line BL, and may output the detected data. In this case, the data output circuit 600 may include an error correction code (ECC) circuit 601. After the start of a read operation, that is, when data that has been stored in the memory cell array 500 is output, the ECC circuit 601 may detect and correct an error included in data that is detected from the memory cell array 500. The ECC circuit 601 may provide the control circuit 100 with the number of data having an error corrected and locations of memory cells that have output the corrected data and the type of error as the ECC information signal ECC_inf. The number of data having an error corrected by the ECC circuit 601 may correspond to the number of memory cells that do not store data normally. If the ECC circuit 601 has corrected data so that the data has the set state, the ECC circuit 601 may have determined that the type of error as a set error. If the ECC circuit 601 has corrected data so that the data has the reset state, the ECC circuit 601 may have determined that the type of error as a reset error.

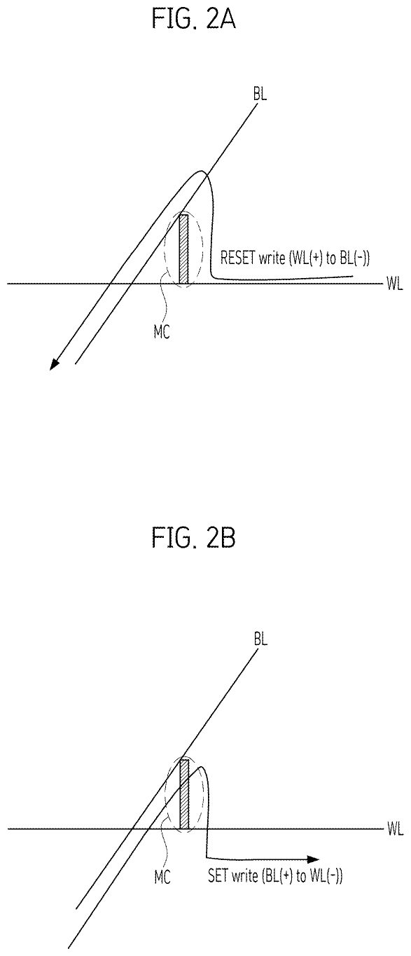

FIGS. 2A, 2B, and 2C are diagrams for describing a reset write operation, a set write operation, and a read operation for a memory cell that is included in a semiconductor device (e.g., the semiconductor device 1000 in FIG. 1) according to an embodiment of the present disclosure.

The memory cell MC may be electrically connected between the word line WL and the bit line BL. The direction of a current that flows into the memory cell MC may be determined depending on the polarity of a voltage that is applied to each of the word line WL and the bit line BL. The state of the memory cell MC may transition to the set state or the reset state based on the direction of the current. In this case, an operation of changing the state of the memory cell MC to the set state or the reset state may be called a write operation. Furthermore, an operation of changing the state of the memory cell MC to the set state may be called a set write operation. An operation of changing the state of the memory cell MC to the reset state may be called a reset write operation. An operation of outputting data that has been stored in the memory cell MC may be called a read operation. An operation of detecting the state of the memory cell MC in order to identify whether the state of the memory cell MC is the set state or the reset state may be an operation that is included in a read operation. Although specific current directions are shown in FIGS. 2A, 2B, and 2C illustrating a reset write operation, a set write operation, and a read operation, respectively, embodiments of the present disclosure are not limited thereto.

Referring to FIG. 2A, a reset write operation for changing the state of the memory cell MC to the reset state may be described as follows.

In a reset write operation, a first bias voltage applied to the selected word line WL is greater than a second bias voltage applied to the selected bit line BL, thereby making the memory cell MC between the selected word and bit lines WL and BL have a reset state (e.g., a high resistance state). For example, when the positive bias voltage V_P (indicated by “+” in FIG. 2) is applied to the word line WL and the negative bias voltage V_N (indicated by “−” in FIG. 2) is applied to the bit line BL, a current may flow from the word line WL to the bit line BL through the memory cell MC. At this time, the state of the memory cell MC may be changed to the reset state.

The reset write operation may be described as follows, for example, with reference to FIG. 1.

The current direction control circuit 200 may apply the positive bias voltage V_P to the row voltage line L_R and apply the negative bias voltage V_N to the column voltage line L_C, based on the current direction control signal I_C for changing the state of the memory cell MC to the reset state.

The row decoder 300 may select one of the plurality of word lines WL based on the row address signal ADD_R, and may drive the selected word line WL to the voltage level of the row voltage line L_R. At this time, the level of the selected word line WL may become substantially equal to the level of the positive bias voltage V_P.

The column decoder 400 may select one of the plurality of bit lines BL based on the column address signal ADD_C, and may drive the selected bit line BL to the voltage level of the column voltage line L_C. At this time, the level of the selected bit line BL may become substantially equal to the level of the negative bias voltage V_N.

As a result, a current may flow from the selected word line WL to the selected bit line BL through a memory cell MC that is electrically connected between the selected word line WL and the selected bit line BL, among the plurality of memory cells MC. At this time, the state of the memory cell MC may be changed to the reset state.

A set write operation for changing the state of the memory cell MC to the set state may be described as follows with reference to FIG. 2B.

In a set write operation, a first bias voltage applied to a selected bit line BL is greater than a second bias voltage applied to a selected word line WL, thereby making the memory cell MC between the selected word and bit lines WL and BL have a set state (e.g., a low resistance state). For example, when the positive bias voltage (+) is applied to the bit line BL and the negative bias voltage (−) is applied to the word line WL, a current may flow from the bit line BL to the word line WL through the memory cell MC. At this time, the state of the memory cell MC may be changed to the set state.

The set write operation may be described as follows, for example, with reference to FIG. 1.

The current direction control circuit 200 may apply the positive bias voltage V_P to the column voltage line L_C and apply the negative bias voltage V_N to the row voltage line L_R, based on the current direction control signal I_C for changing the state of the memory cell MC to the set state.

The row decoder 300 may select one of the plurality of word lines WL based on the row address signal ADD_R, and may drive the selected word line WL to the voltage level of the row voltage line L_R. At this time, the level of the selected word line WL may become substantially equal to the level of the negative bias voltage V_N.

The column decoder 400 may select one of the plurality of bit lines BL based on the column address signal ADD_C, and may drive the selected bit line BL to the voltage level of the column voltage line L_C. At this time, the level of the selected bit line BL may become substantially equal to the level of the positive bias voltage V_P.

As a result, a current may flow from the selected bit line BL to the selected word line WL through a memory cell MC that is electrically connected between the selected word line WL and the selected bit line BL, among the plurality of memory cells MC. At this time, the state of the memory cell MC may be changed to the set state.

Furthermore, referring to FIG. 2C, in order to detect the state of the memory cell MC after the start of a read operation, a current may be made to flow into the memory cell MC in the same direction as a current direction after the start of a set write operation.

In this case, a difference between the levels of voltages that are applied to both ends of the memory cell MC in the reset write direction and the set write direction, that is, a difference between the voltage levels of the word line WL and the bit line BL, may be the same. In other words, an absolute difference between the levels of voltages that are applied to both ends of the memory cell MC in the reset write operation may be substantially the same as an absolute difference between the levels of voltages that are applied to both ends of the memory cell MC in the set write operation. A difference between the voltage levels of the word line WL and the bit line BL in the read operation may be smaller than a difference between the voltage levels of the word line WL and the bit line BL in the reset write or set write operation.

FIGS. 2A, 2B, and 2C describe an operation of applying the positive bias voltage (+) to the word line WL and applying the negative bias voltage (−) to the bit line BL in order to change the state of the memory cell MC to the reset state, whereas an operation of applying the positive bias voltage (+) to the bit line BL and applying the negative bias voltage (−) to the word line WL in order to change the state of the memory cell MC to the set state or detect the state of the memory cell MC. However, embodiments of the present disclosure are not limited to thereto. That is, the direction of a current for changing the state of the memory cell MC to the set state or the reset state and the direction of a current for detecting the state of the memory cell MC may not limited to the directions illustrated in FIGS. 2A, 2B, and 2C.

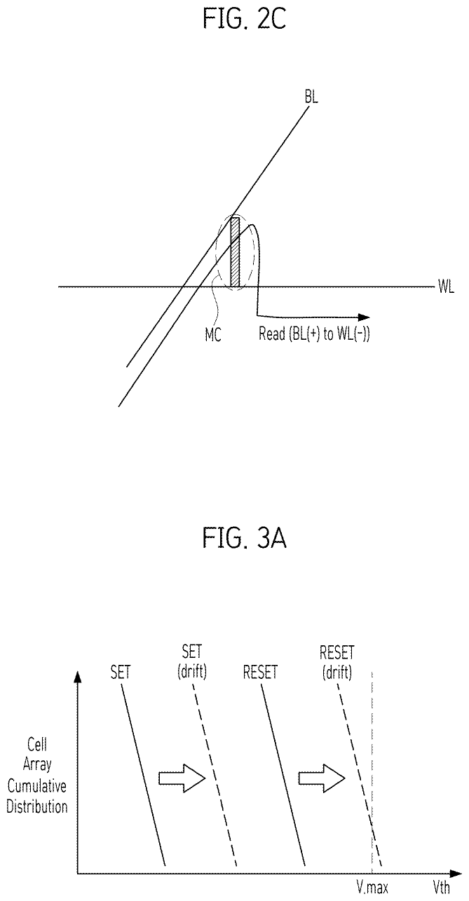

FIGS. 3A and 3B are diagrams for describing a drift phenomenon and re-write operation of a memory cell that is included in the semiconductor device according to an embodiment of the present disclosure. FIGS. 3A and 3B merely describe the memory cell MC constructed so that the level of the threshold voltage Vth of the memory cell MC the state of which has been changed to the set state is lower than the level of the threshold voltage Vth of the memory cell MC the state of which has been changed to the reset state as an example. The present disclosure does not limit the threshold voltage Vth of the memory cell MC, the set state of the memory cell MC, and the reset state of the memory cell MC.

As illustrated in FIG. 3A, the level of the threshold voltage Vth of the memory cell MC having the set state or the reset state may become higher as time elapses. A phenomenon in which the level of the threshold voltage Vth of the memory cell MC having the set state or the reset state become higher as time elapses may be called a drift phenomenon.

An operation of determining whether the state of the memory cell MC is the set state or the reset state after the start of a read operation may be an operation of determining the threshold voltage Vth of the memory cell MC.

For example, an operation of determining the set state or reset state of the memory cell MC may be an operation of detecting the amount of current that is constructed to flow from the bit line BL to the word line WL through the memory cell MC and that passes through the memory cell MC by applying the positive bias voltage V_P to the bit line BL of the memory cell MC and applying the negative bias voltage V_N to the word line WL of the memory cell MC. As illustrated in FIG. 3A, the amount of current that passes through the memory cell MC may be greater when the state of the memory cell MC is the set state than when the state of the memory cell MC is the reset state because the level of the threshold voltage Vth of the memory cell MC having the set state is lower than the level of the threshold voltage Vth of the memory cell MC having the reset state.

Therefore, the reason why whether the state of the memory cell MC is the set state or the reset state can be determined by detecting the amount of current that flows via the memory cell MC after the start of a read operation is that the amount of current that flows via the memory cell MC is different due to the threshold voltage Vth according to the state of the memory cell MC.

Accordingly, if the level of the threshold voltage Vth of the memory cell MC having the set state or the reset state becomes higher due to a drift phenomenon, it is difficult to determine whether the state of the memory cell MC is the set state or the reset state normally. This may degrade data storage reliability of a semiconductor device.

Furthermore, if the threshold voltage Vth in the reset state is greater than a maximum threshold voltage (V.max) due to a drift phenomenon, the state of the memory cell MC may not be changed from the reset state to the set state.

Referring to FIG. 3B, assuming that the level of the threshold voltage Vth of a memory cell in the set state has increased due to a drift phenomenon, the level of the increased threshold voltage Vth due to the drift phenomenon may be lowered when a current having the same direction as a current having a set write direction is applied to the memory cell. In this case, an operation of providing the memory cell having the set state with the current having the same direction as the direction of the current in the set write operation may be named a set re-write operation.

Furthermore, assuming that the level of the threshold voltage Vth of a memory cell in the reset state has increased due to a drift phenomenon, the level of the increased threshold voltage Vth due to the drift phenomenon may be lowered when a current having the same direction as a current having a reset write direction is applied to the memory cell. In this case, an operation of providing the memory cell having the reset state with the current having the same direction as the current in the reset write operation may be named a reset re-write operation.

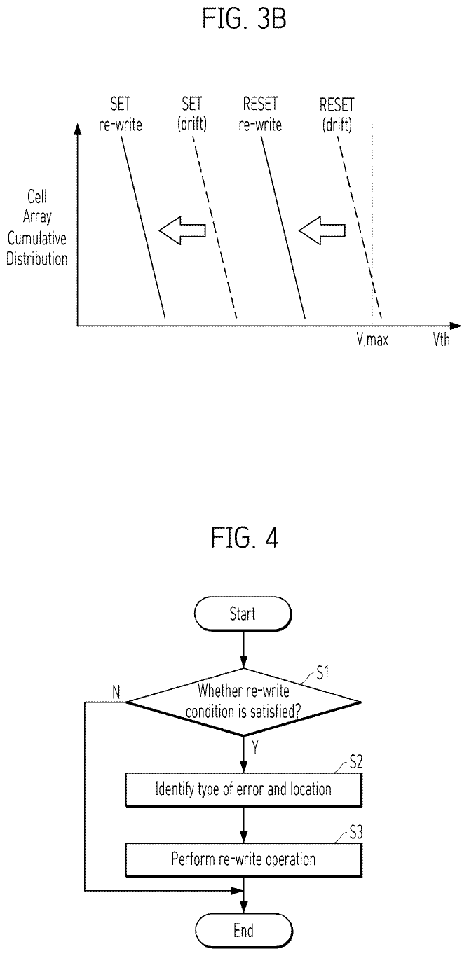

The semiconductor device and operating methods of the semiconductor device according to embodiments of the present disclosure are intended to solve a problem occurring due to the drift phenomenon. Operating methods of a semiconductor device according to embodiments of the present disclosure may be described hereinafter as with reference to FIGS. 4 to 6.

FIG. 4 is a flowchart for describing an operating method of a semiconductor device according to an embodiment of the present disclosure.

Referring to FIG. 4, the operating method of the semiconductor device according to an embodiment of the present disclosure may include an operation S1 of determining whether a re-write condition is satisfied, an operation S2 of identifying the type of error and a location, and an operation S3 of performing a re-write operation.

The operation S1 of determining whether a re-write condition is satisfied may include an operation of determining whether it is necessary to perform a re-write operation on a memory cell. In an embodiment, in the operation S1, a re-write condition may be satisfied if a write operation is not performed on a memory cell although a set time (e.g., 48 hours) elapses, that is, when the time for which the memory cell maintains the same state (i.e., the set state or the reset state) is greater than a set time (e.g., 48 hours). Furthermore, in the operation S1, a re-write condition may be satisfied when the number of data corrected by the ECC circuit 601 after the start of a read operation is greater than a set number.

The operation S2 of identifying the type of error and a location may include an operation of identifying the state (i.e., the reset state or the set state) of data stored in the memory cell that maintains the same state after the elapse of the set time or the location of the memory cells. For example, the operation S2 of identifying the type of error and a location may include an operation of identifying the locations of memory cells that maintain the set state after the elapse of the set time, or the locations of memory cells that maintain the reset state after the elapse of the set time. Furthermore, the operation S2 of identifying the type of error and a location may include an operation of identifying the locations of memory cells in each of which the state of data has been corrected as the set state or the reset state by the ECC circuit 601 after the start of a read operation.

The operation S3 of performing a re-write operation may include an operation of providing a current having the same direction as a current having a set write direction to memory cells that maintain the set state after the elapse of a set time, or to memory cells in each of which the state of data has been corrected as the set state. Furthermore, the operation S3 of performing a re-write operation may include an operation of providing a current having the same direction as a current having a reset write direction to memory cells that maintain the reset state after the elapse of a set time, or to memory cells in each of which the state of data has been corrected as the reset state.

As described above, in the operating method of the semiconductor device according to an embodiment of the present disclosure, a re-write operation is performed on memory cells that maintain the same state after the elapse of a set time, or on memory cells in each of which the state of data has been corrected due to an ECC operation. Accordingly, a data error rate of memory cells can be reduced and data storage reliability of memory cells can be improved by performing a re-write operation on the memory cells with the threshold voltages that have been changed due to a drift phenomenon.

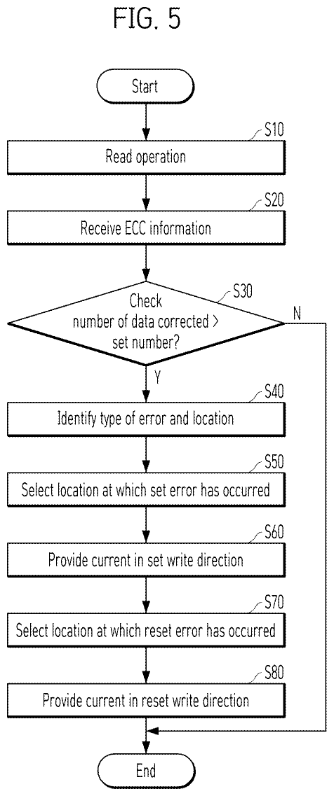

FIG. 5 is a flowchart for describing an operating method of the semiconductor device according to an embodiment of the present disclosure.

Referring to FIG. 5, the operating method of the semiconductor device may include a read operation S10, an operation S20 of receiving ECC information, an operation S30 of checking the number of data corrected, an operation S40 of identifying the type of error and a location, an operation S50 of selecting a location at which a set error has occurred, an operation S60 of providing a current having a set write direction, an operation S70 of selecting a location at which a reset error has occurred, and an operation S80 of providing a current having a reset write direction.

The read operation S10 may include an operation of outputting data that has been stored in the plurality of memory cells MC included in the memory cell array 500, based on the command signal CMD and the address signal ADD.

For example, the read operation S10 may include an operation of detecting data of a memory cell that has been designated by the address signal ADD, based on the command signal CMD and the address signal ADD, or an operation of detecting and correcting an error included in the detected data, or both.

More specifically, the control circuit 100 may generate the current direction control signal I_C, the row address signal ADD_R, and the column address signal ADD_C, based on the command signal CMD and the address signal ADD, and may provide the current direction control signal I_C, the row address signal ADD_R, and the column address signal ADD_C to the current direction control circuit 200, the row decoder 300, and the column decoder 400, respectively. At this time, the current direction control circuit 200 may apply the negative bias voltage V_N to the row voltage line L_R and apply the positive bias voltage V_P to the column voltage line L_C. Alternatively, the current direction control circuit 200 may apply the positive bias voltage V_P to the row voltage line L_R and apply the negative bias voltage V_N to the column voltage line L_C. Furthermore, the row decoder 300 may select at least one of the plurality of word lines WL based on the row address signal ADD_R, and may drive the selected word line WL to the level of the negative bias voltage V_N. The column decoder 400 may select at least one of the plurality of bit lines BL based on the column address signal ADD_C, and may drive the selected bit line BL to the level of the positive bias voltage V_P.

The data output circuit 600 may detect data of a memory cell that is connected between the selected word line WL and the selected bit line BL, based on a current of the selected word line WL or the selected bit line BL, and may output the detected data. In other words, the data output circuit 600 may detect data of a memory cell connected between the selected word line WL and the selected bit line DL based on a current flowing through the memory cell, and may output the detected data. At this time, the ECC circuit 601 may detect and correct an error of the detected data. The ECC circuit 601 may generate information with regard to the number of data corrected and the locations of memory cells at each of which the corrected data has been detected, and the ECC information signal ECC_inf including the type of corrected error, through the operation of detecting and correcting an error. The number of data corrected by the ECC circuit 601 may correspond to the number of memory cells having the shifted level (e.g., increased level) of the threshold voltage Vth due to a drift phenomenon.

The operation S20 of receiving ECC information may include an operation of receiving the ECC information signal ECC_inf that is provided by the ECC circuit 601.

For example, the operation S20 of receiving ECC information may include an operation of receiving, by the control circuit 100, the ECC information signal ECC_inf that is generated by the ECC circuit 601 after the start of a read operation.

The operation S30 of checking the number of data corrected may include an operation of determining whether the number of data having an error corrected by the ECC circuit 601 based on the ECC information signal ECC_inf, that is, the number of memory cells having the shifted level (e.g., increased level) of the threshold voltage Vth due to a drift phenomenon, is greater than a set number.

For example, when the number of data having an error corrected based on the ECC information signal ECC_inf is greater than the set number (Y) in the operation S30 of checking the number of data corrected, the operation S40 of identifying the type of error and a location may be performed.

When the number of data having an error corrected based on the ECC information signal ECC_inf is not greater than the set number (N) in the operation S30 of checking the number of data corrected, the operating method of the semiconductor device according to the embodiment shown in FIG. 5 of the present disclosure may be terminated.

More specifically, the control circuit 100 may perform the operation S30 of checking the number of data corrected on which the operating method of the semiconductor device according to the embodiment in FIG. 5 of the present disclosure may continue to be performed or may be terminated, based on the number of data having an error corrected which is included in the ECC information signal ECC_inf.

The operation S40 of identifying the type of error and a location may include an operation of identifying the locations of memory cells with stored data having an error detected and the type of error corrected, based on the ECC information signal ECC_inf. In this case, if the state of the data has been corrected as the set state, the type of error of the data may be called a set error. If the state of the data has been corrected as the reset state, the type of error of the data may be called a reset error. That is, a set error indicates that the corrected data has a set state, whereas a reset error indicates that the corrected data has a reset state.

For example, the control circuit 100 may perform the operation S40 of identifying the type of error and a location, including generating the row address signal ADD_R and the column address signal ADD_C corresponding to the locations of memory cells that have stored data including an error detected based on the type of error, based on the ECC information signal ECC_inf. In other words, the operation S40 may include generating the row address signal ADD_R and the column address signal ADD_C based on the ECC information signal ECC_inf, where the row and column address signals ADD_R and ADD_C indicate the locations of memory cells from which errors have been detected.

The operation S50 of selecting a location at which a set error has occurred may include an operation of selecting the locations of memory cells in each of which the state of data has been corrected as the set state in the operation S40 of identifying the type of error and a location.

For example, the row decoder 300 and the column decoder 400 may perform the operation S50 of selecting a location at which a set error has occurred, including selecting at least one word line WL and at least one bit line BL based on the row address ADD_R and the column address ADD_C that are provided by the control circuit 100. In this case, the row address ADD_R and the column address ADD_C that are provided by the control circuit 100 may correspond to the locations of memory cells storing data corrected as the set state. For example, the control circuit 100 may generate the row address ADD_R and the column address ADD_C corresponding to first locations of memory cells that have output first data corrected to have the set state.

The operation S60 of providing a current having a set write direction may include an operation of providing the memory cells selected in the operation S50 of selecting a location at which a set error has occurred with a current having the set write direction.

For example, the current direction control circuit 200 may perform the operation S60 of providing a current in a set write direction, which includes driving, by the row decoder 300, the selected word line WL to the level of the negative bias voltage V_N and driving, by the column decoder 400, the selected bit line BL to the level of the positive bias voltage V_P, by providing the positive bias voltage V_P to the column voltage line L_C and providing the negative bias voltage V_N to the row voltage line L_R based on the current direction control signal I_C. In other words, the current direction control circuit 200 may provide the positive bias voltage V_P to the column voltage line L_C and provide the negative bias voltage V_N to the row voltage line L_R based on the current direction control signal I_C. As a result, the column decoder 400 drives the selected bit line BL to the level of the positive bias voltage V_P and the row decoder 300 drives the selected word line WL to the level of the negative bias voltage V_N, thereby providing the selected memory cell with a current in a set write direction.

The operation S70 of selecting a location at which a reset error has occurred may include an operation of selecting the locations of memory cells in which the state of data has been corrected as the reset state in the operation S40 of identifying the type of error and a location.

For example, the row decoder 300 and the column decoder 400 may perform the operation S70 of selecting a location at which a reset error has occurred, including selecting at least one word line WL and at least one bit line BL based on the row address ADD_R and the column address ADD_C that are provided by the control circuit 100. In this case, the row address ADD_R and the column address ADD_C that are provided by the control circuit 100 may correspond to the locations of memory cells storing data corrected as the reset state. For example, the control circuit 100 may generate the row address ADD_R and the column address ADD_C corresponding to second locations of memory cells that have output second data corrected to have the reset state.

The operation S80 of providing a current in a reset write direction may include an operation of providing the memory cells selected in the operation S70 with a current having the reset write direction.

For example, the current direction control circuit 200 may perform the operation S80 of providing a current in a reset write direction, which includes driving the word line WL selected by the row decoder 300 to the level of the positive bias voltage V_P and driving the bit line BL selected by the column decoder 400 to the level of the negative bias voltage V_N by providing the negative bias voltage V_N to the column voltage line L_C and providing the positive bias voltage V_P to the row voltage line L_R based on the current direction control signal I_C. In other words, the current direction control circuit 200 may provide the positive bias voltage V_P to the row voltage line L_R and provide the negative bias voltage V_N to the column voltage line L_C based on the current direction control signal I_C. As a result, the row decoder 300 drives the selected word line WL to the level of the positive bias voltage V_P and the column decoder 400 drives the selected bit line BL to the level of the negative bias voltage V_N, thereby providing the selected memory cell with a current in a reset write direction.

As a result, in the semiconductor device and the operating method of the semiconductor device according to embodiments of the present disclosure, when the number of data having an error corrected based on the ECC information that is generated after the start of a read operation for memory cells is greater than a set number, the locations of the memory cells can be identified based on the type of error corrected, and a current having a direction based on the type of error can be provided to the identified locations of the memory cells. In the embodiment shown in FIG. 5, the operations S50 associated with a set error and a set re-write operation are performed before the operations S70 and S80 associated with a reset error and a reset re-write operation. However, embodiments of the present disclosure are not limited thereto. For example, the operations S70 and S80 associated with a reset re-write operation may be performed before the operations S50 and S60 associated with a set error and a set re-write operation.

Therefore, the semiconductor device and the operating method of the semiconductor device according to embodiments of the present disclosure can adjust (e.g., lower) the levels of the threshold voltages of memory cells, which have shifted (e.g., become higher) due to a drift phenomenon, to the level of a threshold voltage in a normal set or reset state, by providing a current having a reset write direction or a set write operation to the memory cells that do not maintain the normal set or reset state due to the drift phenomenon after the start of a read operation. As a result, the semiconductor device and the operating method of the semiconductor device according to embodiments of the present disclosure can substantially prevent the threshold voltage of a memory cell in which data having the reset state has been stored from exceeding a maximum threshold voltage (V.max) due to a drift phenomenon.

Accordingly, the semiconductor device and the operating method of the semiconductor device according to embodiments of the present disclosure can reduce a data error rate of a memory cell and solve a problem in that a memory cell does not transition from the reset state to the set state, thereby improving the data storage reliability of the memory cell.

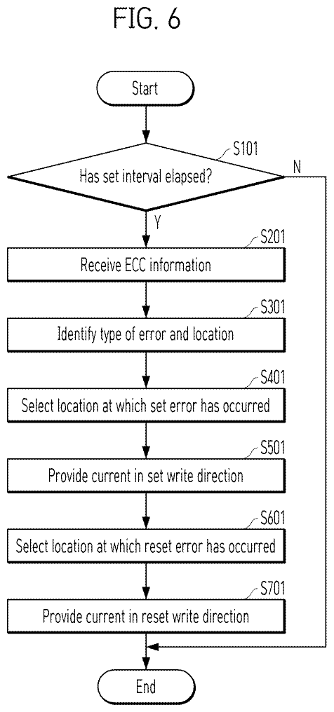

FIG. 6 is a flowchart for describing an operating method of the semiconductor device according to an embodiment of the present disclosure.

Referring to FIG. 6, the operating method of the semiconductor device according to an embodiment of the present disclosure may include an operation S101 of determining an interval, an operation S201 of receiving ECC information, an operation S301 of identifying the type of error and a location, an operation S401 of selecting a location at which a set error has occurred, an operation S501 of providing a current in a set write direction, an operation S601 of selecting a location at which a reset error has occurred, and an operation S701 of providing a current in a reset write direction.

The operation S101 of determining an interval may include an operation of determining whether a set interval has elapsed. For example, the operation S10 may include determining, after a write operation has been performed on a memory cell to make the memory cell have a specific state, whether a set time interval has elapsed during which the memory cell keeps having the specific state.

For example, when it is determined that the set interval has elapsed (Y) in the operation S101 of determining an interval, the operation S201 of receiving ECC information may be performed. In contrast, when it is determined that the set interval has not elapsed (N) in the operation S101 of determining an interval, the operating method of the semiconductor device according to the embodiment shown in FIG. 6 of the present disclosure may be terminated. As a result, the operation S101 of determining an interval may include performing the operation S201 of receiving ECC information every set interval.

More specifically, the control circuit 100 may receive, from the timer 700, the interval information signal T_inf that is generated every set interval. Furthermore, the control circuit 100 may request, from the ECC circuit 601, the ECC information signal ECC_inf that is generated after the start of a just-before read operation whenever the interval information signal T_inf is provided. Specifically, the just-before read operation may refer to a read operation that is performed most recently before the timer 700 provides the interval information signal T_inf to the control circuit 100.

Therefore, the control circuit 100 and the timer 700 may perform the operation S101 of determining an interval, including requesting, from the ECC circuit 601, the ECC information signal ECC_inf that is generated after the start of a just-before read operation whenever a set interval elapses.

The operation S201 of receiving ECC information may include an operation of receiving the ECC information signal ECC_inf that is provided by the ECC circuit 601. For example, the operation S201 of receiving ECC information may include an operation of receiving, by the control circuit 100, the ECC information signal ECC_inf that is generated by the ECC circuit 601 after the start of a read operation just before a timing at which the interval information signal T_inf has been provided to the control circuit 100. That is, the ECC information signal ECC may indicate most recently updated information on the locations of memory cells with corrected errors and types of the corrected errors.

The operation S301 of identifying the type of error and a location may include an operation of identifying the locations of memory cells that have stored data having an error detected and the type of error corrected, based on the ECC information signal ECC_inf. In this case, if the state of the data has been corrected as the set state, the type of error of the data may be called a set error. If the state of the data has been corrected as the reset state, the type of error of the data may be called a reset error.

For example, the control circuit 100 may perform the operation S301 of identifying the type of error and a location, including generating the row address signal ADD_R and the column address signal ADD_C corresponding to the locations of memory cells that have stored data including an error detected based on the type of error, based on the ECC information signal ECC_inf.

The operation S401 of selecting a location at which a set error has occurred may include an operation of selecting the locations of memory cells in each of which the state of data has been corrected as the set state in the operation S301 of identifying the type of error and a location.

For example, the row decoder 300 and the column decoder 400 may perform the operation S401 of selecting a location at which a set error has occurred, including selecting at least one word line WL and at least one bit line BL based on the row address ADD_R and the column address ADD_C that are provided by the control circuit 100. In this case, the row address ADD_R and the column address ADD_C that are provided by the control circuit 100 may correspond to the locations of memory cells storing data corrected as the set state.

The operation S501 of providing a current in a set write direction may include an operation of providing the memory cells selected in the operation S401 with a current having the set write direction.

For example, the current direction control circuit 200 may perform the operation S501 of providing a current in a set write direction, which includes driving the word line WL selected by the row decoder 300 to the level of the negative bias voltage V_N and driving the bit line BL selected by the column decoder 400 to the level of the positive bias voltage V_P by providing the positive bias voltage V_P to the column voltage line L_C and providing the negative bias voltage V_N to the row voltage line L_R based on the current direction control signal I_C.

The operation S601 of selecting a location at which a reset error has occurred may include an operation of selecting the locations of memory cells in which the state of data has been corrected as the reset state in the operation S301 of identifying the type of error and a location.

For example, the row decoder 300 and the column decoder 400 may perform the operation S601 of selecting a location at which a reset error has occurred, including selecting at least one word line WL and at least one bit line BL based on the row address ADD_R and the column address ADD_C that are provided by the control circuit 100. In this case, the row address ADD_R and the column address ADD_C that are provided by the control circuit 100 may correspond to the locations of memory cells storing data corrected as the reset state.

The operation S701 of providing a current in a reset write direction may include an operation of providing the memory cells that have been selected in the operation S601 with a current having the reset write direction.

For example, the current direction control circuit 200 may perform the operation S701 of providing a current in a reset write direction, which includes driving the word line WL selected by the row decoder 300 to the level of the positive bias voltage V_P and driving the bit line BL selected by the column decoder 400 to the level of the negative bias voltage V_N by providing the negative bias voltage V_N to the column voltage line L_C and providing the positive bias voltage V_P to the row voltage line L_R based on the current direction control signal I_C.

As a result, in the semiconductor device and the operating method of the semiconductor device according to embodiments of the present disclosure, the locations of memory cells can be identified based on the type of error of data corrected by the ECC circuit 601 whenever a set interval elapses, and a current having a direction based on the type of error can be provided to the identified locations of the memory cells.

Therefore, the semiconductor device and the operating method of the semiconductor device according to embodiments of the present disclosure can adjust (e.g., lower) the levels of the threshold voltages of memory cells, which have shifted (e.g., become higher) due to a drift phenomenon, to the level of a threshold voltage in a normal set or reset state, by providing a current having a reset write direction or a set write direction to the memory cells that do not maintain the normal set or reset state due to the drift phenomenon, whenever a set interval elapses. As a result, the semiconductor device and the operating method of the semiconductor device according to embodiments of the present disclosure can substantially prevent the threshold voltage of a memory cell in which data having the reset state has been stored from exceeding a maximum threshold voltage (V.max) due to a drift phenomenon, whenever a set interval elapses.

Accordingly, the semiconductor device and the operating method of the semiconductor device according to embodiments of the present disclosure can reduce a data error rate of a memory cell and solve a problem in that a memory cell does not transition from the reset state to the set state, thereby improving the data storage reliability of the memory cell.

Although embodiments according to the technical spirit of the present disclosure have been described above with reference to the accompanying drawings, the embodiments have been provided to merely describe embodiments according to the concept of the present disclosure, and various embodiments of the present disclosure are not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a control circuit configured to generate a current direction control signal, a row address signal, and a column address signal, based on a command signal, an address signal, a data signal, and an error correction code (ECC) information signal;
a current direction control circuit configured to selectively provide a first bias voltage and a second bias voltage to a row voltage line and a column voltage line, based on the current direction control signal;
a row decoder configured to select at least one word line, among a plurality of word lines, based on the row address signal and configured to drive the selected word line to a voltage level of the row voltage line;
a column decoder configured to select at least one bit line, among a plurality of bit lines, based on the column address signal and configured to drive the selected bit line to a voltage level of the column voltage line;
a memory cell array comprising a plurality of memory cells that are disposed at intersecting locations of the plurality of word lines and the plurality of bit lines; and
a data output circuit configured to detect data that has been stored in selected memory cells, among the plurality of memory cells, after a start of a read operation and configured to detect, correct, and output an error of the detected data.

2. The semiconductor device of claim 1, wherein the current direction control circuit selects the row voltage line and the column voltage line to which the first bias voltage and the second bias voltage are provided, based on the current direction control signal, so that voltages having different polarities are provided to the row voltage line and the column voltage line.

3. The semiconductor device of claim 1, wherein:
the data output circuit comprises an ECC circuit configured to detect and correct the error of the data; and
the ECC circuit generates the ECC information signal, the ECC information signal indicating a number of corrected data after the start of the read operation, locations of memory cells that have output the corrected data, and a type of error of the corrected data.

4. The semiconductor device of claim 3, wherein the control circuit generates the row address signal and the column address signal corresponding to the locations of the memory cells that have output the corrected data, when the number of the corrected data is greater than a set number, and
wherein the control circuit generates the current direction control signal based on the type of error of the corrected data.

5. The semiconductor device of claim 4, wherein:
the type of error comprises a set error and a reset error, the set error indicative of the corrected data having a set state, the reset error indicative of the corrected data having a reset state;
the first bias voltage is a positive bias volage and the second bias voltage is a negative bias voltage;
the current direction control circuit provides the positive bias voltage to the column voltage line and the negative bias voltage to the row voltage line based on the current direction control signal that is generated based on the set error; and
the current direction control circuit provides the positive bias voltage to the row voltage line and the negative bias voltage to the column voltage line based on the current direction control signal that is generated based on the reset error.

6. The semiconductor device of claim 5, wherein the corrected data include first data corrected to have the set state and second data corrected to have the reset state,
wherein the control circuit generates the row address signal and the column address signal corresponding to first locations of memory cells that have output the first data, when the current direction control signal based on the set error is generated, and
wherein the control circuit generates the row address signal and the column address signal corresponding to second locations of memory cells that have output the second data, when the current direction control signal based on the reset error is generated.

7. The semiconductor device of claim 3, further comprising a timer configured to generate an interval information signal whenever a set time interval elapses,
wherein the control circuit generates the row address signal and the column address signal corresponding to locations of memory cells that have output the corrected data based on the ECC information signal when the control circuit receives the interval information signal, and
wherein the control circuit generates the current direction control signal based on the type of error of the corrected data.

8. The semiconductor device of claim 7, wherein:
the type of error comprises a set error and a reset error, the set error indicative of the corrected data having a set state, the reset error indicative of the corrected data having a reset state;
the first bias voltage is a positive bias volage and the second bias voltage is a negative bias voltage;
the current direction control circuit provides the positive bias voltage to the column voltage line and the negative bias voltage to the row voltage line based on the current direction control signal that is generated based on the set error; and
the current direction control circuit provides the positive bias voltage to the row voltage line and the negative bias voltage to the column voltage line based on the current direction control signal that is generated based on the reset error.

9. The semiconductor device of claim 8, wherein the corrected data include first data corrected to have the set state and second data corrected to have the reset state,
wherein the control circuit generates the row address signal and the column address signal corresponding to first locations of memory cells that have output the first data, when the current direction control signal based on the set error is generated, and
wherein the control circuit generates the row address signal and the column address signal corresponding to second locations of memory cells that have output the second data, when the current direction control signal based on the reset error is generated.

10. The semiconductor device of claim 3, wherein:
the type of error comprises a set error and a reset error, the set error indicative of the corrected data having a set state, the reset error indicative of the corrected data having a reset state;
the first bias voltage is greater than the second bias voltage;
the current direction control circuit provides the first bias voltage to the column voltage line and the second bias voltage to the row voltage line based on the current direction control signal that is generated based on the set error; and
the current direction control circuit provides the first bias voltage to the row voltage line and the second bias voltage to the column voltage line based on the current direction control signal that is generated based on the reset error.

11. A semiconductor device comprising:
a control circuit configured to generate a current direction control signal, a row address signal, and a column address signal based on an error correction code (ECC) information signal, after a start of a read operation or whenever a set time interval elapses;
a current direction control circuit configured to selectively provide a first bias voltage and a second bias voltage to a row voltage line and a column voltage line, based on the current direction control signal;
a row decoder configured to select at least one word line, among a plurality of word lines, based on the row address signal and configured to drive the selected word line to a voltage level of the row voltage line;
a column decoder configured to select at least one bit line, among a plurality of bit lines, based on the column address signal and configured to drive the selected bit line to a voltage level of the column voltage line; and
an ECC circuit configured to detect and correct an error of data that is output after the start of the read operation, and configured to generate an ECC information signal indicating a number of corrected data, locations of memory cells that have output the corrected data, and a type of error of the corrected data.

12. The semiconductor device of claim 11, wherein the control circuit generates the row address signal and the column address signal corresponding to the locations of the memory cells that have output the corrected data when it is determined that the number of the corrected data is greater than a set number based on the ECC information signal after the start of the read operation, and
wherein the control circuit generates the current direction control signal based on the type of error of the corrected data.

13. The semiconductor device of claim 11, wherein the control circuit generates the row address signal and the column address signal corresponding to the locations of the memory cells that have output the corrected data based on the ECC information signal whenever the set interval elapses, and
wherein the control circuit generates the current direction control signal based on the type of error of the corrected data.

14. The semiconductor device of claim 11, wherein:
the type of error comprises a set error and a reset error, the set error indicative of the corrected data having a set state, the reset error indicative of the corrected data having a reset state; and
the current direction control circuit selects the row voltage line and the column voltage line to which the first bias voltage and the second bias voltage are provided, based on the current direction control signal, so that voltages having different polarities are applied to the row voltage line and the column voltage line.

15. The semiconductor device of claim 14, wherein:
the first bias voltage is greater than the second bias voltage;
the current direction control circuit provides the first bias voltage to the column voltage line and the second bias voltage to the row voltage line based on the current direction control signal that is generated based on the set error; and
the current direction control circuit provides the first bias voltage to the row voltage line and the second bias voltage to the column voltage line based on the current direction control signal that is generated based on the reset error.

16. The semiconductor device of claim 15, wherein the first bias voltage is a positive bias voltage and the second bias voltage is a negative bias voltage.

17. An operating method of a semiconductor device, comprising:
a read operation of outputting data stored in a selected memory cell;
an operation of receiving error correction code (ECC) information from an ECC circuit that detects and corrects an error of the data after a start of a read operation;
an operation of determining whether a number of corrected data is greater than a set number based on the ECC information;
an operation of identifying locations of memory cells that have output the corrected data and a type of error of the corrected data based on the ECC information when the number of data corrected is greater than the set number; and
an operation of providing a current having a direction based on the type of error to the memory cells that have output the corrected data.

18. The operating method of claim 17, wherein the type of error comprises a set error and a reset error, the set error indicative of the corrected data having a set state, the reset error indicative of the corrected data having a reset state,
wherein the memory cells that have output the corrected data include first memory cells having the corrected data as the set state and second memory cells having the corrected data as the reset state, and
wherein the operation of providing the current having the direction based on the type of error to the memory cells comprises:
an operation of providing a positive bias voltage to a bit line of each of the first memory cells and providing a negative bias voltage to a word line of each of the first memory cells, and
an operation of providing the negative bias voltage to a bit line of each of the second memory cells and providing the positive bias voltage to a word line of each of the second memory cells.

19. An operating method of a semiconductor device, comprising:
an operation of receiving error correction code (ECC) information whenever a set time interval elapses;
an operation of identifying locations of memory cells that have output corrected data and a type of error of the corrected error based on the ECC information; and
an operation of providing a current having a direction based on the type of error to the memory cells that have output the corrected data.

20. The operating method of claim 19, wherein the type of error comprises a set error and a reset error, the set error indicative of the corrected data having a set state, the reset error indicative of the corrected data having a reset state,
wherein the memory cells that have output the corrected data include first memory cells having the corrected data as the set state and second memory cells having the corrected data as the reset state,
wherein the operation of providing the current having the direction based on the type of error to the memory cells comprises:
an operation of providing a positive bias voltage to a bit line of each of the first memory cells and providing a negative bias voltage to a word line of each of the first memory cells; and
an operation of providing the negative bias voltage to a bit line of each of the second memory cells and providing the positive bias voltage to a word line of each of the second memory cells.
